(19) United States
(12) Patent Application Publication
(10) Pub. No.: US 2008/0073774 A1
(43) Pub. Date: Mar. 27, 2008

(54) CHIP PACKAGE AND CHIP PACKAGE ARRAY

(75) Inventors: Wen-Kun Yang, Hsinchu City (TW); Dyi-Chung Hu, Hsinchu County (TW); Chih-Ming Chen, Hsinchu County (TW); Hsien-Wen Hsu, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: ADVANCED CHIP ENGINEERING TECHNOLOGY INC., Hsinchu County (TW)

(21) Appl. No.: 11/566,242

(22) Filed: Dec. 4, 2006

(30) Foreign Application Priority Data
Sep. 21, 2006 (TW) 95134930

(51) Int. Cl. H01L 23/04

(52) U.S. Cl. 257/698

(57) ABSTRACT

A chip package including a multilayer substrate, an adhesive core layer and a chip is provided. The multilayer substrate has a plurality of material layers. The adhesive core layer is disposed on the multilayer substrate. The chip is disposed in the adhesive core layer. The chip has an active surface exposed outside the adhesive core layer. The chip includes a plurality of bonding pads disposed on the active surface and a plurality of metal conductive bodies electrically connected to the bonding pads respectively.

### CROSS-REFERENCE TO RELATED APPLICATION

This application claims the priority benefit of Taiwan application serial no. 95134930, filed on Sep. 21, 2006. All disclosure of the Taiwan application is incorporated herein by reference.

### BACKGROUND OF THE INVENTION

1. Field of the Invention

The present invention relates to a semiconductor element. More particularly, the present invention relates to a chip package and a chip package array.

2. Description of Related Art

In the semiconductor industry, the production of integrated circuits (ICs) is mainly divided into three stages, i.e., wafer fabrication, IC process and IC package. A chip is fabricated through the following steps such as wafer fabrication, circuit design, mask fabrication and wafer sawing. Each chip formed by wafer sawing, after being electrically connected to an external carrier through the bonding pads disposed thereon, is further encapsulated by a molding compound. The objective of package lies in preventing the chip from the impact of moisture, heat and noise and providing a medium for electrically connecting the chip and an external circuit.

However, in the conventional IC packaging process, after a wafer is sawed into a plurality of chips, the contacts on a chip are electrically connected to an external carrier through a wire bonding process or flip chip bonding process. Therefore, the conventional IC packaging process is complicated and the cost of the carrier is also very high. In order to eliminate the above-mentioned disadvantages, how to skip the step of electrically connecting a chip to an external carrier and thus make the chip directly and electrically connected to a next-level electronic device (i.e., a next-level electronic device of the carrier, for example, a main board) in the packaging process should be considered.

For example, a package has been disclosed in ROC Patent No. 177766. FIG. 1 is a schematic side view of a conventional chip package array. As shown in FIG. 1, the chip package array 100 includes a hard substrate 110, an adhesive core layer 120, a plurality of chips 130 and a redistribution layer (RDL) 140. The adhesive core layer 120 is disposed on the hard substrate 110 and the chips 130 are disposed in the adhesive core layer 120. Each chip 130 has an active surface 132 exposed outside the adhesive core layer 120. Moreover, each chip 130 includes a plurality of bonding pads 134 disposed on the active surface 132 and a plurality of metal conductive bodies 136 disposed on the bonding pads 134 respectively, wherein the metal conductive bodies can be metal bumps or metal balls. The RDL 140, disposed on the active surface 132 and the adhesive core layer 120, has a plurality of contacts 142 electrically connected to the bonding pads 134 respectively, wherein the metal conductive bodies 136 are disposed on the contacts 142.

The subsequent fabrication of a dielectric layer and elements (for example, the RDL 140 and the metal conductive bodies 136) and singularizing operation in combination with an existing wafer process machine after the arrangement of the chips 130 may be carried out on above-mentioned conventional chip package array 100 to saw the chip package array 100 into a plurality of chip package units. When the conventional chip package array 100 undergoes the singularizing process, a cutting tool (not shown) is first used to cut in from the adhesive core layer 120 between two adjacent chips 130 and proceeds towards the hard substrate 110 till the two adjacent chips 130 are completely separated. It should be noted that the conventionally adopted hard substrate 110 is made of a single-layer metal (for example, a copper or an iron-nickel alloy with a commercial name of, for example, Alloy 42) or glass, silicon. Thus, when the cutting tool is used to cut the hard substrate 110, a large acting force is required, which may easily cause damages to the cutting tool and shorten the lifetime thereof. Moreover, the edge of the hard substrate 110 is also easily to be scraped or warped and causes damages to other material layers due to the stress effect in the cutting. As such, the yield of the overall process is affected and the cost is increased.

### SUMMARY OF THE INVENTION

Accordingly, the present invention is directed to a chip package, wherein the substrate thereof is easy to cut and is relatively flat.

The present invention is also directed to a chip package array, wherein the substrate thereof is easy to cut and is relatively flat after being cut such that the yield of the singularizing process is promoted and the abrasion of the cutting tool is alleviated. Thus, the fabrication cost is reduced.

As embodied and broadly described herein, the present invention provides a chip package comprising a multilayer substrate, an adhesive core layer and a chip. The multilayer substrate comprises a plurality of material layers, and the adhesive core layer is disposed on the multilayer substrate. Moreover, the chip is disposed in the adhesive core layer, and the active surface of the chip is exposed outside the adhesive core layer. In addition, the chip further comprises a plurality of bonding pads disposed on the active surface and a plurality of metal conductive bodies electrically connected to the bonding pads respectively.

In an embodiment of the present invention, the multilayer substrate comprises at least one first material layer and at least one second material layer interlaced with the first material layer. The number of the first material layer is, for example, one and the number of the second material layer is, for example, two. Thus, the first material layer is disposed between the second material layers and one of the second material layers contacts the adhesive core layer.

In an embodiment of the present invention, the material of the above-mentioned first material layer is, for example, a polymer and the material of the second material layers is, for example, a metal. In addition, the material of the first material layer comprises bismaleimide-triazine resin (i.e., BT resin), epoxy resin, or either pure adhesive compound or a composite material with adhesive material partially filled with filler. Filler can be fiber glass, silicon particle or other types of different size or shape filler materials. The material of the second material layers comprises copper or iron-nickel alloy, for example, the composition of the copper or iron-nickel alloy is included in a commercial brand product, namely Alloy 42.

Alternatively, according to an embodiment of the present invention, the material of the second material layers may also be comprised of the above-mentioned polymer, for example, BT resin, epoxy resin, or either pure adhesive compound or a composite material with adhesive material partially filled with filler. Filler can be fiber glass, silicon particle or other types of different size or shape filler materials. The material of the first material layer is comprised of the above-mentioned metal, for example, copper or iron-nickel alloy.

In an embodiment of the present invention, the first material layer has a plurality of cavities and the second material layers fill up the cavities, wherein the cavities are, for example, through holes.

In an embodiment of the present invention, at least one of the material layers has a plurality of dents which are located on the edge of the at least one material layer.

In an embodiment of the present invention, the material of the adhesive core layer comprises silicone rubber, polyurethane resin (i.e., PU resin) or acrylic resin (i.e., the so-called acrylic).

In an embodiment of the present invention, the above-mentioned chip package further comprises an RDL disposed on the active surface and the adhesive core layer. The RDL has a plurality of contacts electrically connected to the bonding pads respectively and the metal conductive bodies are correspondingly disposed on the contacts.

In an embodiment of the present invention, the above-mentioned chip package further comprises a cover layer. The cover layer and the adhesive core layer are disposed on the two opposite sides of the multilayer substrate respectively.

In an embodiment of the present invention, the above-mentioned metal conductive bodies are, for example, metal balls or metal bumps.

The present invention further provides a chip package array comprising a multilayer substrate, an adhesive core layer and a plurality of chips. The multilayer substrate comprises a plurality of material layers, and the adhesive core layer is disposed on the multilayer substrate. Moreover, the chips are disposed in the adhesive core layer, and the active surface of each chip is exposed outside the adhesive core layer. In addition, each chip further comprises a plurality of bonding pads disposed on the active surface and a plurality of metal conductive bodies electrically connected to the bonding pads respectively.

In an embodiment of the present invention, the multilayer substrate comprises at least one first material layer and at least one second material layer which are interlaced. The number of the first material layer is, for example, one and the number of the second material layer is, for example, two. The first material layer is disposed between the second material layers and one of the second material layers contacts the adhesive core layer.

In an embodiment of the present invention, the material of the above-mentioned first material layer comprises, for example, a polymer and the material of the second material layers comprises, for example, a metal. The material of the first material layer comprises BT resin, epoxy resin, or either pure adhesive compound or a composite material with adhesive material partially filled with filler. Filler can be fiber glass, silicon particle or other types of different size or shape filler materials. The material of the second material layers comprises copper or iron-nickel alloy.

Alternatively, according to another embodiment of the present invention, the material of the second material layers may be comprised of the above-mentioned polymer, for example, BT resin, epoxy resin, or either pure adhesive compound or a composite material with adhesive material partially filled with filler. Filler can be fiber glass, silicon particle or other types of different size or shape filler materials. The material of the first material layer may be comprised of the above-mentioned metal, for example, copper or iron-nickel alloy.

In an embodiment of the present invention, the first material layer has a plurality of cavities and the second material layers fill Up the cavities, wherein the cavities are, for example, through holes.

In an embodiment of the present invention, at least one of the above-mentioned material layers has a plurality of holes. A portion of the holes are arranged along a plurality of parallel first straight lines and the rest of the holes are arranged along a plurality of parallel second straight lines. Each first straight line and each second straight line are substantially perpendicular to each other and the adjacent chips are spaced by the holes.

In an embodiment of the present invention, the material of the above-mentioned adhesive core layer comprises silicone rubber, PU resin or acrylic resin.

In an embodiment of the present invention, the above-mentioned chip package array further comprises an RDL disposed on the active surfaces and the adhesive layer. The RDL has a plurality of contacts electrically connected to the bonding pads respectively and the metal conductive bodies are disposed on the contacts.

In an embodiment of the present invention, the above-mentioned chip package array further comprises a cover layer. The cover layer and the adhesive layer are disposed on two opposite sides of the multilayer substrate respectively.

In an embodiment of the present invention, the above-mentioned metal conductive bodies are, for example, metal balls or metal bumps.

In view of the above, the present invention adopts a multilayer substrate constituted by a variety of material layers. The arrangement of the material layers may be altered during the cutting process to achieve a predetermined supporting effect, so as to achieve an optimal cutting effect. Thus, the process yield may be effectively promoted, and the abrasion of the cutting tool may be alleviated to reduce the fabrication cost.

In order to make the aforementioned and other objectives, features and advantages of the present invention comprehensible, preferred embodiments accompanied with figures are described in detail below.

### BRIEF DESCRIPTION OF THE DRAWINGS

FIG. 1 is a schematic side view of a conventional chip package array.

FIG. 2 is a schematic side view of a chip package array according to an embodiment of the present invention.

FIG. 3 is a schematic top view of the chip package array in FIG. 2.

FIG. 4A is a schematic side view of a multilayer substrate according to another embodiment of the present invention.

FIG. 4B is a schematic side view of a multilayer substrate according to yet another embodiment of the present invention.

FIG. 5 is a schematic side view of a chip package according to an embodiment of the present invention.

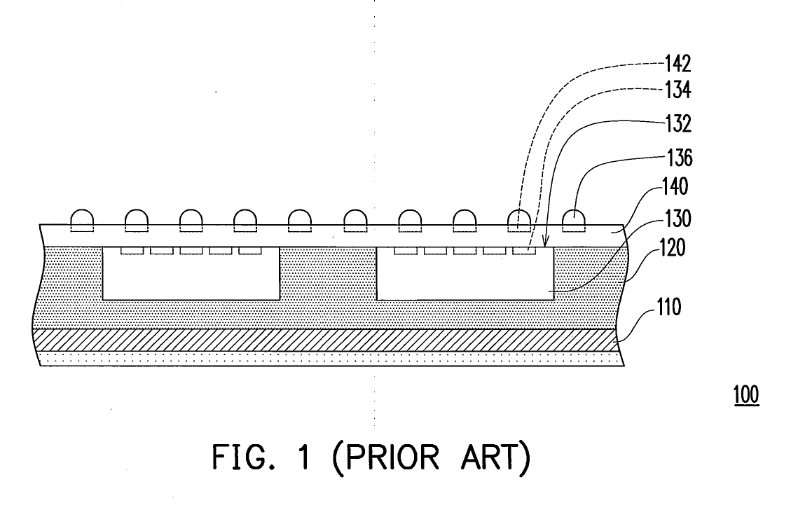

### DESCRIPTION OF EMBODIMENTS

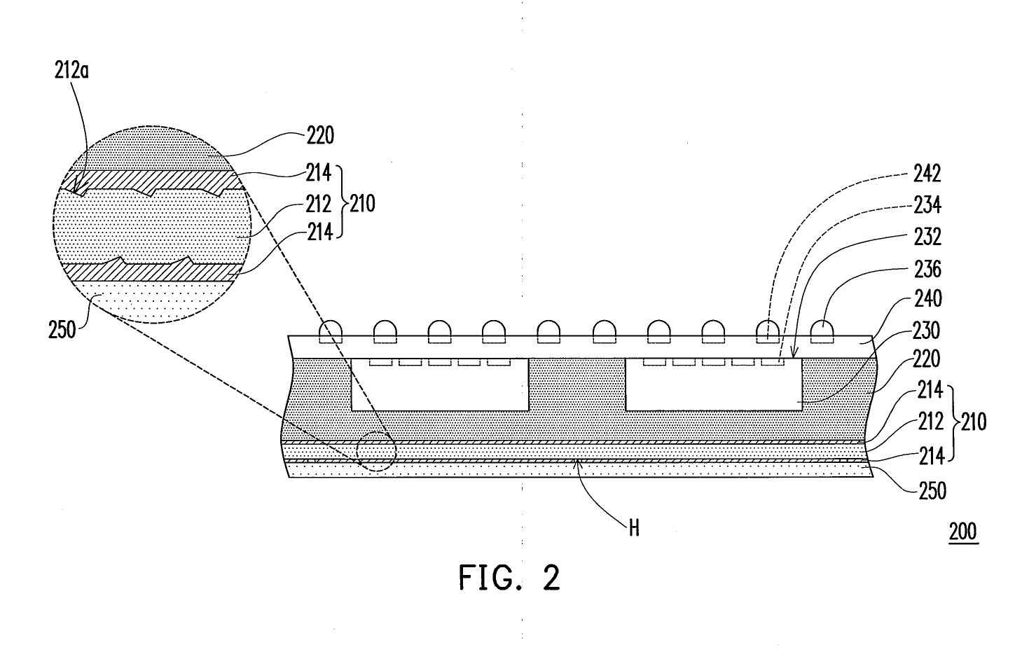

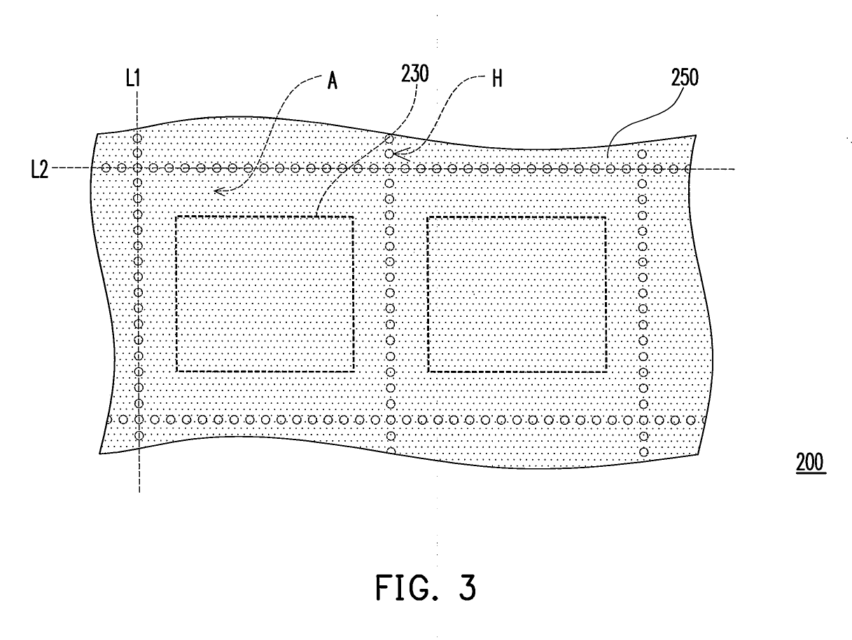

FIG. 2 is a schematic side view of a chip package array according to an embodiment of the present invention. FIG. 3 is a schematic top view of the chip package array in FIG. 2. Firstly, referring to FIG. 2, the chip package array 200 of this embodiment includes a multilayer substrate 210, an adhesive core layer 220 and a plurality of chips 230. The multilayer substrate 210 has a plurality of material layers 212, 214, and the adhesive core layer 220 is disposed on the multilayer substrate 210. The chips 230 are disposed in the adhesive core layer 220, and each chip 230 has an active surface 232 exposed outside the adhesive core layer 220. Moreover, each chip 230 includes a plurality of bonding pads 234 disposed on the active surface 232 and a plurality of metal conductive bodies 236 (for example, metal balls or metal bumps) electrically connected to the bonding pads 234 respectively. As the multilayer substrate 210 has a plurality of material layers 212, 214, and is easy to cut when the chip package array 200 during a subsequent singularizing process, which will be described in detail below.

In this embodiment, the above-mentioned multilayer substrate 210 includes at least one first material layer 212 and at least one second material layer 214 interlaced with the first material layer. Besides, the number of the first material layer 212 may be one and the number of the second material layer 214 may be two. The first material layer 212 is disposed between the second material layers 214 and one of the second material layers 214 contacts the adhesive core layer 220. In particular, as for the relative position in FIG. 2, the adhesive core layer 220 is disposed on the upper second material layer 214. Moreover, the material of the first material layer 212 is a polymer, for example, BT resin, epoxy resin, or either pure adhesive compound or a composite material with adhesive material partially filled with filler. Filler can be fiber glass, silicon particle or other types of different size or shape filler materials. The material of the second material layers 214 is a metal, for example, copper or iron-nickel alloy.

It should be illustrated herein that the multilayer substrate 210 of this embodiment has three layers as an example and is characterized in having a symmetrical film layer structure. Accordingly, as the multilayer substrate 210 has a symmetrical film layer structure, the stress effect during the cutting process may be compensated, and the multilayer substrate 210 can maintain a preferable flatness after being cutting. Thus, the process yield may be effectively promoted.

Of course, the material layers of the multilayer substrate employed in the present invention are not limited to only three layers or comprised of the above-mentioned materials. The multilayer substrate of the present invention may also be constituted with a variety of different material layers and is not limited to a symmetrical structure as will be described in the following embodiments.

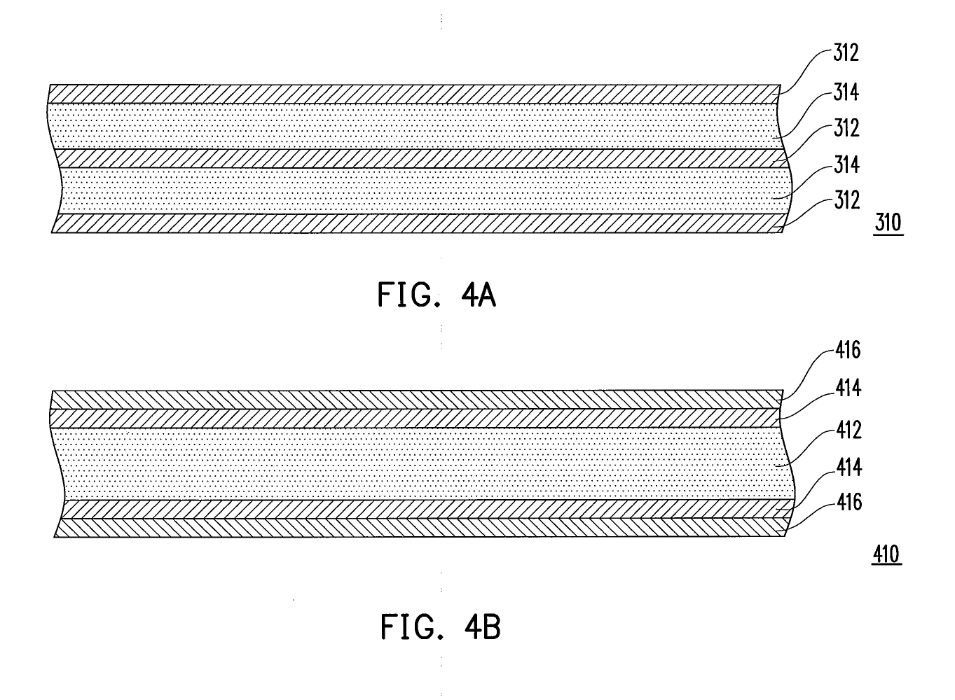

Referring to FIG. 4A, it is a schematic side view of a multilayer substrate according to another embodiment of the present invention. The multilayer substrate 310 has, for example, five layers. The intermediate layer of the multilayer substrate 310 is a first material layer 312 (the material thereof is, for example, a metal), and a second material layer 314 (the material thereof is, for example, a polymer) and another first material layer 312 are sequentially disposed on either of the two opposite sides of the first material layer 312, such that the multilayer substrate 310 of five layers is generally formed by interlaced first material layers 312 and second material layers 314. FIG. 4B is a schematic side view of a multilayer substrate according to yet another embodiment of the present invention. The multilayer substrate 410 has, for example, five layers. The intermediate layer of the multilayer substrate 410 is a first material layer 412 (the material thereof is, for example, a polymer), and a second material layer 414 (the material thereof is a metal) and a third material layer 416 (the material thereof is another metal) are sequentially disposed on either of the two opposite sides of the first material layer 412. In addition, the layer number of the multilayer substrate can be varied according to the requirements (for example, cutting effect or cost), and the material of each layer can also be varied depending on the design requirements.

Referring to FIG. 2, the multilayer substrate 210 can be formed by sputtering and electroplating the second material layers 214 at both sides of the first material layer 212 or by lamination. Besides, the first material layer 212 of the multilayer substrate 210 in this embodiment have a plurality of cavities 212a and the second material layers 214 fill up the cavities 212a. The cavities 212a are used to improve the joint between the first material layer 212 and the second material layers 214. In addition, it should be noted that the cavities 212a can be through holes (not shown) for reinforcing the joint between the first material layer 212 and the second material layers 214. Moreover, in this embodiment, the material of the adhesive core layer 220 includes silicone rubber, PU resin or acrylic resin, and the adhesive core layer 220 can be a blue tape or a UV tape. The adhesive core layer 220 can be formed by means of spin coating, printing or injection molding.

Again referring to FIG. 2, the chip package array 200 further includes an RDL 240 disposed on the active surfaces 232 and the adhesive core layer 220. The RDL 240 has a plurality of contacts 242 electrically connected to the bonding pads 234 respectively and the metal conductive bodies 236 are disposed on the contacts 242. The RDL 240 usually has an interconnect structure (not shown). The bonding pads 234 of each chip 230 can be electrically connected to the regularly arranged contacts 242 (for example, arranged in an array) via the interconnect structure, so as to be further electrically connected to a next-level electronic device (not shown). In this embodiment, the chip package array 200 further includes a cover layer 250, wherein the cover layer 250 and the adhesive core layer 220 are respectively disposed on two opposite sides of the multilayer substrate 210. The cover layer 250 is used to protect the multilayer substrate 210 from being scraped by external forces or affected by the outside temperature and moisture.

Referring to FIGS. 2 and 3, in this embodiment, at least one of the above material layers 212, 214 (only taking the lower second material layer 214 as an example here for illustration) may have a plurality of holes H. A portion of the holes H are arranged along a plurality of parallel first straight lines L1 and the rest of the holes H are arranged along a plurality of parallel second straight lines L2. Each first straight line L1 and each second straight line L2 are substantially perpendicular to each other and the adjacent chips 230 are spaced by the holes H. In other words, the orthographic projections of the chips 230 on the second material layer 214 away from the adhesive core layer 220 (i.e., the lower second material layer 214) are respectively located in a plurality of regions A enclosed by the first straight lines L1 and the second straight lines L2. It should be illustrated herein that as the chip package array 200 has the holes H, when a subsequent singularizing cutting process is carried out, the holes H can provide the cutting tool (not shown) with cutting paths (i.e., the first straight lines L1 and the second straight lines L2) and facilitate the operation of the cutting tool.

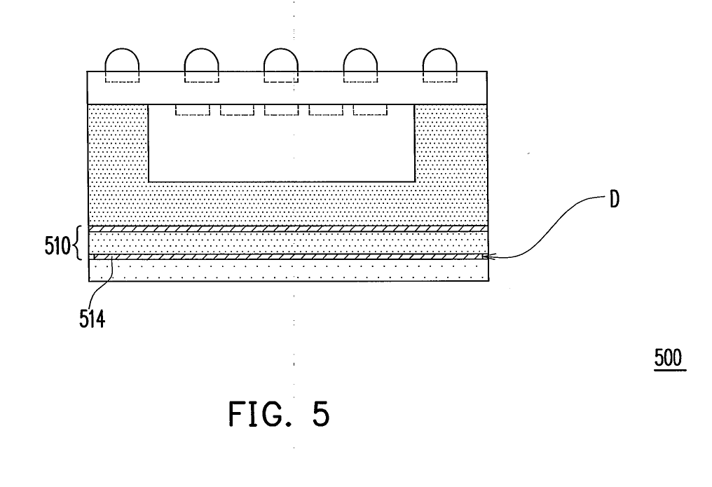

FIG. 5 is a schematic side view of a chip package according to an embodiment of the present invention. A plurality of chip packages 500 (only one is schematically shown in FIG. 5) is formed after the above singularizing process is carried out. It should be noted that the lower second material layer 514 of the multilayer substrate 510 of the chip package 500 has a plurality of dents D disposed on the edge of the lower second material layer 514. The dents D are formed by the holes H of the above chip package array 200 after the cutting step. It should be emphasized that the cut marks at the edge of the multilayer substrate 510 of the singularized chip package 500 are less obvious and the multilayer substrate 510 remains relatively flat after being cut.

In view of the above, the chip package and the chip package array of the present invention at least have the following advantages:

First, as the multilayer substrate has a plurality of material layers, the multilayer substrate is easier to cut when a subsequent singularizing process of the chip package array of the present invention is carried out.

Secondly, as the multilayer substrate may have a symmetrical film layer structure, when a subsequent singularizing process of the chip package array of the present invention is carried out, the stress effect during the cutting process is compensated, thus making the multilayer substrate relatively flat after the cutting.

Thirdly, as the multilayer substrate is advantageous in being easy to cut, having less obvious cut marks after the cutting and being relatively flat after the cutting, the chip package array of the present invention facilitates improving the process yield and alleviating the abrasion of the cutting tool, thereby reducing the process cost.

Fourthly, as the multilayer substrate has a plurality of material layers, the multilayer substrate still maintains certain supporting effect.

Fifthly, as the multilayer substrate has a plurality of material layers, the weight of the multilayer substrate is light and the manufacturing cost thereof is low.

Though the present invention has been disclosed above by the preferred embodiments, they are not intended to limit the present invention. Anybody skilled in the art can make some modifications and variations without departing from the spirit and scope of the present invention. Therefore, the protecting range of the present invention falls in the appended claims.

What is claimed is:

1. A chip package, comprising:
a multilayer substrate, having a plurality of material layers;
an adhesive core layer, disposed on the multilayer substrate; and
a chip, disposed in the adhesive core layer, wherein the chip has an active surface exposed outside the adhesive layer, and the chip comprises:
a plurality of bonding pads, disposed on the active surface; and
a plurality of metal conductive bodies, electrically connected to the bonding pads respectively.

2. The chip package as claimed in claim 1, wherein the multilayer substrate comprises at least one first material layer and at least one second material layer interlaced with the first material layer.

3. The chip package as claimed in claim 2, wherein the chip package comprises one first material layer and two second material layer, and wherein the first material layer is disposed between the second material layers and one of the second material layers contacts the adhesive layer.

4. The chip package as claimed in claim 3, wherein a material of the first material layer comprises a polymer and a material of the second material layers comprises a metal.

5. The chip package as claimed in claim 4, wherein the material of a first material layer comprises bismaleimide-triazine resin (BT resin) or epoxy resin.

6. The chip package as claimed in claim 4, wherein the material of the second material layers comprises copper or iron-nickel alloy.

7. The chip package as claimed in claim 3, wherein a material of the second material layers comprises a polymer, and a material of the first material layer comprises a metal.

8. The chip package as claimed in claim 7, wherein a material of the second material layers comprises BT resin or epoxy resin.

9. The chip package as claimed in claim 7, wherein a material of the first material layer comprises copper or iron-nickel alloy.

10. The chip package as claimed in claim 2, wherein a first material layer comprises a plurality of cavities, and the second material layers fill up the cavities.

11. The chip package as claimed in claim 10, wherein the cavities are through holes.

12. The chip package as claimed in claim 1, wherein at least one of the material layers has a plurality of dents disposed on the edge of the at least one material layer.

13. The chip package as claimed in claim 1, wherein the material of the adhesive core layer comprises silicone rubber, polyurethane resin (PU resin) or acrylic resin.

14. The chip package as claimed in claim 1, further comprising a redistribution layer (RDL) disposed on the active surface and the adhesive layer, wherein the RDL has a plurality of contacts electrically connected to the bonding pads respectively and the metal conductive bodies are disposed on the contacts.

15. The chip package as claimed in claim 1, further comprising a cover layer, wherein the cover layer and the adhesive core layer are respectively disposed on two opposite sides of the multilayer substrate.

16. The chip package as claimed in claim 1, wherein the metal conductive bodies are metal balls or metal bumps.

17. A chip package array, comprising:
a multilayer substrate, having a plurality of material layers;
an adhesive core layer, disposed on the multilayer substrate; and
a plurality of chips, respectively disposed in the adhesive core layer, wherein each chip has an active surface is exposed outside the adhesive core layer, and each chip comprises:
a plurality of bonding pads, disposed on the active surface; and
a plurality of metal conductive bodies, electrically connected to the bonding pads respectively.

18. The chip package array as claimed in claim 17, wherein the multilayer substrate comprises at least one first material layer and at least one second material layer interlaced with the first material layer.

19. The chip package array as claimed in claim 18, wherein the chip package array comprises one first material layer and two second material layer, and wherein the first material layer is disposed between the second material layers and one of the second material layers contacts the adhesive core layer.

20. The chip package array as claimed in claim 19, wherein the material of the first material layer comprises a polymer and the material of the second material layers comprises a metal.

21. The chip package array as claimed in claim 20, wherein a material of the first material layer comprises BT resin or epoxy resin.

22. The chip package array as claimed in claim 20, wherein a material of the second material layers comprises copper or iron-nickel alloy.

23. The chip package array as claimed in claim 19, wherein a material of the second material layers comprises a polymer and a material of the first material layer comprises a metal.

24. The chip package array as claimed in claim 23, wherein a material of the second material layers comprises BT resin or epoxy resin.

25. The chip package array as claimed in claim 23, wherein a material of the first material layer comprises copper or iron-nickel alloy.

26. The chip package array as claimed in claim 18, wherein a first material layer has a plurality of cavities and the second material layers fill up the cavities.

27. The chip package array as claimed in claim 26, wherein the cavities are through holes.

28. The chip package array as claimed in claim 17, wherein at least one of the material layers has a plurality of holes, a portion of the holes are arranged along a plurality of parallel first straight lines and the rest of the holes are arranged along a plurality of parallel second straight lines, each of the first straight lines and each of the second straight lines are substantially perpendicular to each other and the adjacent chips are spaced by the holes.

29. The chip package array as claimed in claim 17, wherein a material of the adhesive core layer comprises silicone rubber, PU resin or acrylic resin.

30. The chip package array as claimed in claim 17, further comprising an RDL disposed on the active surfaces and the adhesive core layer, wherein the RDL has a plurality of contacts electrically connected to the bonding pads respectively and the metal conductive bodies are disposed on the contacts.

31. The chip package array as claimed in claim 17, further comprising a cover layer, wherein the cover layer and the adhesive core layer are respectively disposed on two opposite sides of the multilayer substrate.

32. The chip package array as claimed in claim 17, wherein the metal conductive bodies comprise metal balls or metal bumps.
